(19) United States
(12) Patent Application Publication
(10) Pub. No.: US 2011/0317326 A1
(43) Pub. Date: Dec. 29, 2011

(54) DISCHARGE GAP FILLING COMPOSITION AND ELECTROSTATIC DISCHARGE PROTECTOR

(75) Inventors: Mina Onishi, Tokyo (JP); Yoshimitsu Ishihara, Tokyo (JP); Hirofumi Inoue, Tokyo (JP); Yukihiko Azuma, Tokyo (JP)

(73) Assignee: SHOWA DENLO K.K., Minato-ku, Tokyo (JP)

(21) Appl. No.: 13/254,288

(22) PCT Filed: Mar. 1, 2010
(86) PCT No.: PCT/JP2010/053209

§ 371 Date: Sep. 1, 2011

(30) Foreign Application Priority Data
Mar. 5, 2009 (JP) 2009-051450

(51) Int. Cl. H05F 1/00; C08L 83/04; C08K 9/02; H05K 1/00; H05K 7/00

(52) U.S. Cl. 361/212; 174/250; 174/254; 361/749; 524/430

(57) ABSTRACT

A discharge gap filling composition for an electrostatic discharge protector. The composition contains oxide film coated metal particles (A), a layered substance (B) and a binder component (C). Also disclosed is an electrostatic discharge protector including a discharge gap and a discharge gap filling material containing the discharge gap filling composition that is filled in the discharge gap.

### TECHNICAL FIELD

The present invention relates to a discharge gap filling composition and an electrostatic discharge protector, more specifically it relates to an electrostatic discharge protector having excellent regulating accuracy at an operating voltage and capable of decreasing the size and the cost and also relates to a discharge gap filling composition used for this electrostatic discharge protector.

Electrostatic discharge (hereinafter optionally referred to ESD) is one destructive and inevitable phenomenon that electric systems and integrated circuits are exposed. From the electric viewpoint, ESD is a transient high electric current phenomenon such that a peak current of several amperes continues for a period time of 10 n sec and 300 n sec. Therefore, the occurrence of ESD causes un-repairable damage, wrong conditions or deterioration in its integrated circuit, and thereby the integrated circuit does not work normally unless the electric current of several amperes is conducted to the outside of the integrated circuit within several ten nano sec. In recent years, furthermore, a marked tendency of weight decreasing, thickness decreasing and downsizing has proceeded in electronic parts and electronic equipments. According to the tendency, the integration degree of semiconductors and the packaging density of electronic parts in printed wiring boards are remarkably increased so that electronic elements and signal lines, which are densely integrated or mounted, are very closely present each other. Consequently, high-frequency radiation noise is easily induced together with the acceleration of the rate of signal processing.

Conventionally, as an electrostatic protection element for protecting IC and the like in a circuit from ESD, JP-A-2005-353845 discloses an element having a bulk structure which element comprises a sintered matter of a metal oxide or the like. This element is a laminated chip varistor formed from the sintered matter and is equipped with a laminate and a pair of external electrodes. The varistor has a property such that when an applied voltage reaches a certain definite value or more, a current, which has not flown until then, flows quickly, and also has excellent property capable of preventing electrostatic discharge. The laminated chip varistor, which is a sintered matter, is inevitably produced by a complicated process comprising sheet molding, internal electrode printing, sheet lamination and the like, and has a problem such that wrong conditions such as interlayer delamination and the like are easily induced during mounting steps.

Furthermore, as an electrostatic protection element for protecting IC and the like in circuits from ESD, there is a discharge type element. The discharge type element has a small leaked current, is fundamentally simple and is difficult to have breakdown. The discharge voltage thereof can be controlled by the distance of a discharge gap. When it has a sealing structure, the distance of the discharge gap is determined according to the pressure and the kind of a gas. As a substantially commercial element, there is an element obtainable by forming a conductor film on a cylindrical ceramic surface, providing a discharge gap on the film by a leaser and sealing. This commercial glass sealed tube type discharge gap element has excellent electrostatic discharge properties but a complicated formation. Therefore, it has problems such that the size thereof is limited as a small sized surface mounting element and the cost is hardly decreased.

Moreover, the following documents disclose a method of forming a discharge gap on a wiring directly and regulating a discharge voltage by the distance of the discharge gap. For example, JP-A-H3 (1991)-89588 discloses that the distance of a discharge gap is 4 mm, and JP-A-H5 (1995)-67851 discloses that the distance of a discharge gap is 0.15 mm. JP-A-H10 (1998)-27668 discloses that the discharge gap is preferably 5 to 60 μm in order to protect general electronic elements, the discharge gap is preferably 1 to 30 μm in order to protect IC or LSI sensitive to static electricity, and the discharge gap can be made to have a large size of about 150 μm in the use of only removing a large pulse voltage part.

Unless there is no protection for the discharge gap part, the application at a high voltage can cause aerial discharge, the moisture and gases in the environment can cause contamination on conductor surface and thereby the discharge voltage is changed, or the carbonization of a substrate provided with electrodes occasionally causes short circuit on the electrodes. Furthermore, since this electrostatic discharge protector is required to have high insulating resistance at a normal operating voltage, for example, at a voltage of less than DC10V, it is effective to provide a voltage resistant insulating member on the discharge gap of the electrode pair. When a resist is directly filled in the discharge gap as an insulating member in order to protect the discharge gap, it is not practical because the discharge voltage is vastly increased. When a usual resist is filled in a narrow discharge gap having a very narrow width of about 1 to 2 μm or less, the discharge voltage can be decreased, but the resist filled therein is minutely deteriorated and thereby the insulating resistance is lowered and conduction is occasionally caused.

JP-A-2007-266479 discloses a protective element such that a discharge gap having a width of 10 μm to 50 μm is provided on an insulating substrate and a functional film containing ZnO as a main component and silicon carbide is provided between a pair of electrode patterns which ends are faced each other. As compared with a laminated chip varistor, the protective element has a merit that the constitution is simple and the element can be produced as a thick film element on the substrate. These elements having measures for ESD are made to decrease the mounting area in accordance with the progress of electronic devices. However, the form thereof is an element and the design has low variation in order to mount on a wiring substrate by solder and the like and they have limits on downsizing including a height. Therefore, it is desired to take measures for ESD to necessary places and necessary areas with a free form including downsizing without fixing elements.

Meanwhile, WO-2001-52340 (Patent document 1) discloses a resin composition as an ESD protecting material. This resin composition comprises a main material of an insulating binder mixture, conductive particles having an average particle diameter of less than 10 μm and semiconductor particles having an average particle diameter of less than 10 μm. This document discloses U.S. Pat. No. 4,726,991 (Patent document 2) filed by Hyat et al. The patent document 2 discloses a composition material in which a mixture of conductive particles having surfaces covered with an insulating oxide film and conductor particles is bonded with an insulating binder, a composition material having a defined particle diameter range, and a composition material having a defined surface distance between conductive particles. In the process of the document, the method of dispersing the conductive particles and semiconductor particles is not optimized. The process has technically unstable factors that a high electric resistance value is not obtained at a low voltage and a low electric resistance value is not obtained at a high voltage.

A lighting protector disclosed in JP-B-H7 (1995)-118361 (Patent document 3) discloses a known lighting arrester is known as a device of defending other devices from surging utilizing insulating breakdown phenomenon of a high resistant film provided on the metal surface. In the document, molybdenum is selected as a metal having an oxide film and a molybdenum lighting protector is realized. In this molybdenum light protector, even if insulating breakdown once happens in the oxide film, the oxide film is automatically formed again for a short period of time unless it is placed in an oxidation atmosphere. Therefore, it is can be used repeatedly and does not need to be changed for a long period of time, so that it is a very useful device.

The voltage level of surging is almost same as that of electrostatic discharge, but the current sometime reaches 1000 to 10,000 A. The metal having an oxide film only can exhibit the effect of sufficiently defending other devices from surging. However, since the current of electrostatic electricity is remarkably smaller as compared with surging, only the metal having an oxide film sometimes has insufficient electrostatic discharge protecting properties toward electrostatic discharge.

JP-A-2007-262446 (Patent document 4) discloses a reduction calcining process as a process of forming a conductive part by reducing the surface oxide film of metal particles. It also discloses that when a mixture of metal oxide particles coated with an organic protecting material or metal particles having a surface oxide film and a carbon material is calcined in an oxidizing gas containing oxygen and further calcined in an inert gas, the metal oxide film is reduced by the carbon material to show excellent conducting properties. When the metal oxide film is used for an electrostatic discharge protector, it is necessary to keep the insulating properties in a low voltage condition so that it is impossible to apply the material disclosed herein, as it is, for the electrostatic discharge protector.

Moreover, JP-A-2003-59616 (Patent document 5) discloses a surging absorbing element obtainable by providing a discharge inductor made from an easy electron generating material containing a carbon material in a discharge gap for preventing short circuit. It also discloses that in this element, the discharge voltage can be set to less than 1 KV. The element, however, has a problem that it has instability caused by operation with deformation of the discharge inductor in flowing a surging current and the production process for forming the element is complicated because it is necessary to provide voids.

### PRIOR ARTS

### Patent Documents

Patent document 1: WO-2001-523040
Patent document 2: U.S. Pat. No. 4,726,991
Patent document 3: JP-B-H7 (1995)-118361
Patent document 4: JP-A-2007-262446
Patent document 5: JP-A-2003-59616

### SUMMARY OF THE INVENTION

### Subject to be Solved by the Invention

The present invention is intended to solve the above problems and it is an object of the present invention to provide an electrostatic discharge protector capable of simply preventing ESD with a free form in electronic circuit boards of various designs, having excellent regulation accuracy at an operating voltage and also capable of decreasing the size and cost, and it is another object of the invention to provide a discharge gap filling composition used for the production of the electrostatic discharge protector.

### Means for Solving the Subjects

The present inventors have been earnestly studied in order to solve the above problems in the prior arts and found that the electrostatic discharge protector having excellent regulation accuracy at an operating voltage and capable of decreasing the size and coat can be prepared by regulating a discharge gap of one pair of electrodes in a specific distance, filling the gap with a composition of specific components and solidifying or curing.

That is to say, the present invention relates to the following subjects.

[1] The discharge gap filling composition used for an electrostatic discharge protector according to the present invention comprises oxide film coated metal particles (A), a layered substance (B) and a binder component (C).

[2] The discharge gap filling composition according to [1] wherein the oxide film coated metal particles (A) comprise particles of a single metal selected from the group consisting of manganese, niobium, zirconium, hafnium, tantalum, molybdenum, vanadium, nickel, cobalt, chromium, magnesium, titanium and aluminum, or comprise particles of at least two different metals of the above metals.

[3] The discharge gap filling composition according to [1] or [2] wherein the layered substance (B) is at least one selected from a clay mineral crystal (B1) and a layered carbon material (B2).

[4] The discharge gap filling composition according to [3] wherein the layered substance (B) is the layered carbon material (B2).

[5] The discharge gap filling composition according to [4] wherein the layered carbon material (B2) is at least one selected from the group consisting of carbon nano tube, gas phase grown carbon fiber, carbon fullerene, graphite and a carbyne carbon material.

[6] The discharge gap filling composition according to any one of [1] to [5] wherein the binder component (C) comprises a polysiloxane compound.

[7] The electrostatic discharge protector of the present invention comprises a discharge gap and a discharge gap filling material that is filled in the discharge gap wherein the discharge gap filling material comprises the discharge gap filling composition as described in anyone of [1] to [6] and the discharge gap has a distance of 5 to 300 μm.

[8] The electronic circuit board of the present invention is provided with the electrostatic discharge protector as described in [7].

[9] The electronic circuit board according to [8] which is a flexible electronic circuit board.

[10] The electronic equipment of the present invention is provided with the electronic circuit board as described in [8] or [9].

### Effect of the Invention

The electrostatic discharge protector of the present invention can be formed by forming a discharge gap between necessary electrodes in accordance with a necessary operating voltage, filling the discharge gap with the discharge gap filling composition of the present invention and solidifying or curing. On this account, the use of the discharge gap filling composition of the present invention can produce a small size electrostatic discharge protector in low cost and realize electrostatic discharge protection simply. Since the use of the discharge gap filling composition of the present invention can regulate the operating voltage by regulating the discharge gap in a specific distance, the electrostatic discharge protector of the present invention has excellent regulating accuracy at an operating voltage. Furthermore, the electrostatic discharge protector of the present invention is suitably used for digital devices including cellular phones and mobile devices that they are frequently handled and static electricity is easily charged therein.

### BRIEF DESCRIPTION OF DRAWING

FIG. 1 is a vertical section of an electrostatic discharge protector 11, which is one embodiment of the electrostatic discharge protector according to the present invention.

FIG. 2 is a vertical section of an electrostatic discharge protector 21, which is one embodiment of the electrostatic discharge protector according to the present invention.

FIG. 3 is a vertical section of an electrostatic discharge protector 31, which is one embodiment of the electrostatic discharge protector according to the present invention.

### EMBODIMENT FOR CARRYING OUT THE INVENTION

The present invention will be described in detail below.

### <Discharge Gap Filling Composition>

### Oxide Film Coated Metal Particles (A)

The oxide film coated metal particles (A) used in the present invention are particles obtainable by, on the surfaces of particles of a metal, forming a film of an oxide of the metal. It is considered that although the oxide film coated metal particles (A) has insulating properties at a normal voltage because the oxide film has insulating properties, the oxide film coated metal particles (A) has electrically conductive properties by breakage of the oxide film in loading at a high voltage at the time of electrostatic discharge, and the oxide film is formed again by release of a high voltage and thereby the insulating properties are revived.

The preferable metal particles used in the present invention are metal particles having an oxide film on their surfaces and a volume resistance value of 10⁸ Ω/cm² or more at a normal operating voltage, for example, DC10V even in the metal particles which are highly filled and thereby are adjoined and connected. The metal oxide is a passive state because the free electron movement is constrained. However, when a metal, which is more easily ionized, is oxidized, it is made into a firmer insulator.

Meanwhile, a metal, which is excessively easily ionized, is hardly made into a single metal and the insides of the metal particles are occasionally oxidized. Therefore, the metal particles of the present invention preferably have properties such that nevertheless the ionization tendency is high, a minute oxide film can be formed on their surfaces and thereby the insides thereof can be protected, namely they are preferably in a passive state. Examples of the metal capable of forming such metal particles are manganese, niobium, zirconium, hafnium, tantalum, molybdenum, vanadium, nickel, cobalt, chromium, magnesium, titanium and aluminum. Among them, aluminum, nickel, tantalum and titanium are preferred in the viewpoint of low cost and easy acquisition. The above metal may be an alloy of these metals or several kinds of metal particles may be combined for use.

Furthermore, vanadium used for a thermister which resistance value is largely changed at a specific temperature can be used effectively. The oxide film coated metal particles (A) may be used singly or several kinds may be combined for use.

The oxide film coated metal particles (A) can be prepared by heating metal particles in the presence of oxygen and further an oxide film having a more stable structure can be prepared in the following method. That is to say, in order that the breakdown voltage of the oxide film on the metal surface is not uneven in one product or between products, for example, the surfaces of oxide film coated metal particles are cleaned with an organic solvent such as acetone, and the surfaces are slightly etched by dilute hydrochloric acid and heated in an atmosphere of a mixed gas of 20% of hydrogen and 80% of argon at a temperature lower than the melting point of the metal itself, i.e. at 750° C. for metals other than aluminum, at 600° C. for aluminum for about 1 hr, and further heated in an atmosphere of high purity oxygen for 30 min and thereby a uniform oxide film can be formed with high controllability and good reproducibility.

The preferable oxide film coated metal particles (A) have an average particle diameter, which differs depending on the distance of a pair of electrodes, of preferably not less than 0.01 μm and not more than 30 μm. When the average particle diameter is larger than 30 μm, oxidation of the surface film broken by reduction at the time of ESD generation delays and regeneration of the insulating properties tends to delay because the amount of the oxide film per weight unit of the metal particles is lower as compared with the amount of the inside conductive part that is not oxidized. When the average particle diameter is less than 0.01 μm, in the weight proportion of the oxide film and the conductive part per weight unit, the weight of the oxide film is biased to be larger and the operating voltage at the time of ESD generation sometimes increases. The average particle diameter is evaluated by a 50% cumulative mass diameter. The 50% cumulative mass diameter is obtainable by adding 1% by mass of metal particles for measurement to methanol, dispersing for 4 min by means of ultrasonic homogenizer at a 150 W output and measuring by means of a laser diffraction type light scattering particle size distribution meter Microtrac MT3300 (manufactured by Nikkiso Co., Ltd.).

The oxide film coated metal particles (A) may be present in a state that they contact each other because the metal particles are coated with the surface oxide film and show insulating properties. However, in the case that the proportion of the binder component is small, a problem such as power falling and the like is sometimes caused. The volume occupancy of the oxide film coated metal particles (A) is preferably less than 80% by volume in the solid components of the discharge gap filling composition in consideration of practicability rather than operating properties.

When ESD is generated and thereby the metal particles having a broken surface oxide film show conductivity, the minimum of the volume occupancy has a preferable range because the resulting electrostatic discharge protector needs to show conductivity as a whole. The volume occupancy of the oxide film coated metal particles (A) is preferably not less than 30% by volume in the solid components of the discharge gap filling resin composition. Namely, the volume occupancy of the oxide film coated metal particles (A) in a state that the electrostatic discharge protector is formed is preferably not less than 30% by volume and less than 80% by volume.

The volume occupancy can be determined by subjecting the cross section of a cured product of the discharge gap filling composition to energy dispersion type X-ray analysis by mean of a scanning electron microscope JSM-7600F (manufactured by JEOL Ltd.), and evaluating with the volume proportion of the observation field that the resulting element occupies.

### Layered Substance (B)

The layered substance (B) is a substance formed by a plurality of layers combined through van der Waals force, which substance is a compound such that an atom, molecule or ion which is not concerned with the crystal inherently can be incorporated at a specific position of the crystal by ion exchange and thereby the crystal structure is not changed. The position where an atom molecule or ion incorporates, that is, the host position has a planar layer structure. Typical examples of the layered substance (B) are a clay mineral crystal (B1), a layered carbon material (B2) such as graphite, and a transition metal chalcogenide compound. These compounds exhibit unique properties by incorporating a metal atom, inorganic molecule or organic molecule as a guest in their crystals.

The layered substance (B) has a property that the distance of the layers is flexibly corresponding with the size of a gust and the interaction of the gust. The compound obtainable by incorporating the gust into the host is called as an intercalation compound and there are very various intercalation compounds in combination of the host and the gust. The gust in the layers is different from one adsorbed on the surface and is present in a peculiar environment that it is constrained by the host layers from the two directions. Therefore, it is considered that the property of the intercalation compound is dependent on not only the structure and property of each gust but also the host-guest interaction. Moreover, recently, the layered substance (B) has been studied on the points that it absorbs electromagnetic wave well and when it is an oxide, it becomes an oxygen absorbing and releasing material capable of absorbing or releasing oxygen at a certain temperature. It is considered that these properties influence breakage and reproduction of the oxide film of the oxide film coated metal particles (A).

Examples of the clay mineral crystal (B1) in the layered substance (B) used in the present invention may include smectites clay, which is a swelling silicate, and swelling mica. Specific examples of the smectites clay are montmorillonite, beidellite, nontronite, saponite, ferrous saponite, hectorite, sauconite, stevensite and bentonite, and their substituents and derivatives, and mixtures thereof. Specific examples of the swelling mica are lithium type taeniolite, sodium type taeniolite, lithium type tetrasilicic mica and sodium type tetrasilicic mica, and their substituents and derivatives, and mixtures thereof. Some of the swelling micas have the structure same as that of vermiculite and it is also possible to use such an equivalent for vermiculite.

As the layered substance (B) used in the present invention, the layered carbon material (B2) can be also used. The layered carbon material (B2) can release free electrons in the space between the electrodes at the time of ESD generation. The layered carbon material (B2), further, reduces a metal oxide because of heat storing at the time of ESD generation, and causes phase transition of the lattice structure of the oxide film interface by the heat to change the Schottky rectification properties. As a result, the oxide film coated metal particles (A) showing insulating properties are changed to show conductive properties. Moreover, in the layered carbon material (B2), the internal resistance is increased by oxidation with oxygen generated at the time of over charging, but after the ESD generation, the layered carbon material (B2) is an oxygen-feeding source for reproducing the oxide films of the metal particles.

Examples of the layered carbon material (B2) are a substance obtainable by treating cokes at a low temperature, carbon black, a metal carbide, carbon whisker and SiC whisker. It is confirmed that they have operating properties for ESD. Since they have a carbon atom hexagonal network basic structure, a relatively small layer number and a relatively low regularity, they tend to easily get into short circuit. Therefore, preferable examples of the layered carbon material (B2) are carbon nano tube, gas phase grown carbon fiber, carbon fullerene, graphite and a carbine type carbon material because they have regularity in lamination. The layered carbon material (B2) desirably contains at least one of them or a mixture thereof. Furthermore, recently the fibrous layered carbon material (B2), such as carbon nano tube, graphite whisker, filamentous carbon, graphite fiber, superfine carbon tube, carbon tube, carbon fibril, carbon micro tube and carbon nano fiber have been industrially noticed on not only mechanical strength but also electric field liberating function and hydrogen storage function. The properties are considered to relate an oxidation-reduction reaction. Moreover, it is possible to mix these layered carbon material (B2) and an artificial diamond.

In particular, the hexagonal crystal carbon material which is a hexagonal plate-like flat crystal, the trigonal or rhomb face crystal graphites having high lamination regularity and the carbine type carbon material having a structure such that carbon atoms form a straight chain, and in the straight chain, a single bond and a triple bond are arranged repeatedly or carbon atoms are bonded with a double bond are suitable as a catalyst capable of promoting the oxidation and the reduction of the metal particles because other atoms, ions or molecules can be easily intercalated between the layers. Namely, the layered carbon materials (B2) indicated herein is characterized in that it can intercalate any of an electron donor and an electron acceptor.

In order to remove impurities, the layered carbon materials (B2) may be previously treated at a high temperature of about 2500 to 3200° C. in an inert gas atmosphere or at a high temperature of about 2500 to 3200° C. in an inert gas atmosphere together with a graphitizing catalyst such as boron, boron carbide, beryllium, aluminum or silicon.

As the layered substance (B), the clay mineral crystal (B1) such as swelling silicate and swelling mica, and the layered carbon material (B2) may be individually used or two or more may be combined for use. Among them, smectic clay, graphite and gas phase grown carbon fiber are preferably used because of having dispersibility in the binder component (C) and easiness in acquisition.

When the layered substance [B] has a spherical or scale-like form, the average particle diameter is preferably not less than 0.01 μm and not more than 30 μm.

In the case that the average particle diameter of the layered substance (B) is over 30 μm, particularly in the layered carbon material (B2), continuity in particles is easily induced and thereby it is sometimes difficult to prepare a stable ESD protector. On the other hand, in the case that it is less than 0.01 μm, it has high cohesive force and production problems such as high charging properties and the like are sometimes induced. When the layered substance (B) has a spherical or scale-like form, the average particle diameter is evaluated by a 50% cumulative mass diameter in the following manner. 50 mg of a sample is weighed and added to 50 mL of distilled water. Furthermore, 0.2 mL of a 2% Triton aqueous solution (Trade name, a surface active agent manufactured by GE Health Care Bio Science Co. Ltd.) was added to the mixture and dispersed with an ultrasonic homogenizer of a 150 W output for 3 min, and then measured by a leaser diffraction light scattering particle size distribution meter, for example, leaser diffraction light scattering particle size distribution meter (Trade Mark: Microtrac MT3300, manufactured by Nikkiso Co., Ltd.).

The layered substance (B) having a fibrous form preferably has an average fiber diameter of not less than 0.01 μm and not more than 0.3 and an average fiber length of not less than 0.01 μm and not more than 20 μm, and more preferably an average fiber diameter of not less than 0.06 μm and not more than 0.2 μm, and an average fiber length of not less than 1 μm and not more than 20 μm. The average fiber diameter and the average fiber length of the fibrous layered substance (B) can be determined by measuring, for example, 20 to 100 fibers with an electron microscope and taking an average.

In the case that the layered carbon material (B2) is used as the layered substance (B), continuity of the carbon materials (B2) between the electrodes must be avoided in order to keep the insulating properties at the time of normal operating. Therefore, the volume occupancy of the layered carbon material (B2) is important in addition to the dispersibility and the average particle diameter. In the case that the clay mineral crystal (B1) such as swelling silicate and swelling mica is used as the layered substance (B), it is sufficiently effective to add it in an amount of capable of partly damaging the oxide films of the metal particles.

Therefore, in the layered substance (B) having a spherical or scale-like form, the volume occupancy of the layered carbon material (B2) is desirably not less than 0.1% by volume and not more than 10% by volume in the solid components of the discharge gap-filling resin composition. When the volume occupancy is more than 10% by volume, continuity in the carbon atoms is easily induced and thereby the resin or substrate is broken because the heat reserve is large at the time of ESD discharging, and after ESD generation, the recovery of the insulating properties of an ESD protector tends to be late by high temperatures. On the other hand, when it is less than 0.1% by volume, the operating properties for ESD protection is sometimes unstable.

The layered substance (B) having a fibrous form is more effectively contact with the surfaces of the metal particles (A) as compared with the layered substance (B) having a spherical or scale-like form, and it is easily conducted by the excess amount thereof. Therefore, the layered substance (B) having a fibrous form has preferably a low volume occupancy of not less than 0.01% by volume and not more than 5% by volume as compared with the layered substance (B) having a spherical or scale-like form.

### Binder Component (C)

The binder component (C) is an insulating substance capable of dispersing the oxide film coated metal particles (A) and the layered substance (B) therein and functioning as a medium between the oxide film coated metal particles (A) and the layered substance (B). Examples of the binder (C) are organic polymers, inorganic polymers and their mixed polymers. Among them, a polysiloxane compound is preferred by the following reasons.

Since the composition of the present invention contains the oxide film coated metal particles (A), the binder component (C) preferably has a functional group capable of reacting with a metal oxide. As a result of various examinations, it has been found that an alkoxysilane sol-gel reaction product is reacted with a metal oxide to fix the metal particles (A), and a polysiloxane compound obtainable from the alkoxysilane having a specific functional group in the side chain stably fixes the oxide film coated metal particles (A) and can remarkably induce the properties as an ESD protector. Particularly, a polysiloxane compound having a ladder structure has a favorable molecule structure in the point of heat resistance and it is very preferred in order that the ESD protector is defended from heating caused by ESD discharging.

Additionally, as a carbon ring or hetero ring polymer having a ladder structure, it is possible to use polyacene, or polyperynaphthalene, which are difficult to be produced.

As the alkoxysilane, a trialkoxysilane represented by the formula (1) is preferable.

RSi(OR′)₃ (1)

R is an alkyl group having 1 to 8 carbon atoms such as a methyl group, an ethyl group and an n-isopropyl group, a phenyl group, a γ-chloropropyl group, a vinyl group, a 3,3,3-chloropropyl group, a γ-glycidoxypropyl group and a 3,4-epoxycyclohexylethyl group. R′ is an alkyl group having 1 to 8 carbon atoms.

The polysiloxane compound is obtainable by hydrolyzing and condensing these trialkoxysilanes in the presence of an acid. Furthermore, after increasing the molecular weight with condensation by adding a basic group, water and a salt present therein are removed and thereby the polysiloxane compound may be prepared. Moreover, dialkyldialkoxysilane and tetra-alkoxysilane are used and co-condensed. The polysiloxane compound has a weight average molecular weight, determined by GPC measurement relative to polystyrene, of preferably 500 to 50,000. When the weight average molecular weight is less than 500, cracks are occasionally caused in the discharge gap-filling member. Particularly, when the polysiloxane compound is only used as the binder component (C), it is preferred to use the polysiloxane compound having the above molecular weight range.

As the polysiloxane compound other than the above compounds, a silicon elastomer and a silicon resin can be used and they may be used simultaneously with a silicon oil. Moreover, a polysilosesquioxane can be also used.

Examples of the silicon oil are a straight silicon type oil substituted by a hydrocarbon group (polydimethyl siloxane, polymethylphenyl siloxane and polymethyl hydrogen siloxane), a non-reaction type modified silicon oil, a reaction type modified silicon oil modified with an amino group, an epoxy group, alcohol, a mercapto group or a carboxyl group, and a copolymerization type modified silicon oil such as polyoxyalkylene, a higher alcohol or an aliphatic acid.

Examples of the silicon elastomer may include a crosslinking reaction product of a crosslinking agent and a base polymer such as polysiloxane having a substituted or un-substituted mono-valent hydrocarbon group. According to the crosslinking reaction type, there are a room temperature condensation curing type liquid silicon rubber, a heat vulcanization type silicon rubber and a liquid heat vulcanization type silicon rubber.

Examples of the silicon resin are highly crosslinked resins obtainable by copolymerizing a polyfunctional siloxane component in the structure. Usually straight silicon type resins obtainable by substituting with a hydrocarbon group are used and further, resins obtainable modifying with an epoxy or alkyd may be used.

As the silicon resin, it is effective to use a commercially available silicon resin. For example, Trade Names TSE3033, X14-2334 and X14-B3445 manufactured by Momentive Performance Materials Japan Inc., are preferably used.

Furthermore, as the polysiloxane compound, a siloxane-containing polyimide is also preferable. In this case, while the oxide film coated metal particles (A) are fixed at the siloxane linking position, the resin crosslinking can be conducted. Because of having an imide structure, the siloxane-containing polyimide shows excellent adhesion in the case of polyimide materials such that a substrate is a printed wiring board. A commercially available example of the siloxane-containing polyimide is Trade Name “polyimide-siloxane SPI” manufactured by Nippon Steel Chemical Co., Ltd.

For the poly-functional epoxy resin having a secondary hydroxyl group, an alkoxy group-containing silane modified epoxy resin obtainable by conducting dealcohol condensation reaction of an alkoxysilane part condensate in the absence of a solvent corresponds to the polysiloxane compound of the present invention. The electrostatic discharge protector can be prepared in a slow curing condition by a method of using a binder component (C) obtainable by mixing the alkoxy group-containing silane modified epoxy resin, an epoxy resin curing agent and a silanol condensation accelerating agent, or a method of using a binder component (C) obtainable by mixing the alkoxy group-containing silane modified epoxy resin and a polyamic acid. Examples of the alkoxy group-containing silane modified resin further may include a phenol resin and a urethane resin which are available as COMPOCERAN series manufactured by Arakawa Chemical Industries Ltd. in addition to the epoxy resin and the polyamic acid.

It is possible to mix the polysiloxane compound with a resin other than the polysiloxane compound. Examples of the resin other than the polysiloxane compound are a phenol resin, an unsaturated polyester resin, an epoxy resin, a vinyl ester resin, an alkyd resin, an acryl resin, a melamine resin, a xylene resin, a guanamine resin, a diarylphthalate resin, an arylester resin, a furane resin, an imide resin, an urethane resin and an urea resin.

In the case of using the polysiloxane compound singly or in the case of the combined use of the resin other than the polysiloxane compound, the polysiloxane compound is added in an amount of preferably not less than 5 parts by mass based on 100 parts by mass of the oxide film coated metal particles (A). When the amount is less than 5 parts by mass, the fixing of the oxide film coated metal particles (A) is insufficient and thereby repeating application of a high voltage sometimes easily causes short circuit.

### Other Components

The discharge gap filling composition of the present invention may optionally comprise a curing catalyst, a curing accelerating agent, a filler, a solvent, a foaming agent, a defoaming agent, a leveling agent, a lubricant, a plasticizer, a rust preventive, a viscosity regulator and a colorant in addition to the oxide film coated metal particles (A), the layered substance (B) and the binder component (C). Moreover, it may comprise insulating particles such as silica particles and the like.

### Production Process of Discharge Gap Filling Composition

In producing the discharge gap filling composition of the present invention, for example, the oxide film coated metal particles (A), the layered substance (B) and the binder component (C), and further the other components, such as the solvent, the filler, the curing catalyst etc, are dispersed and mixed using a disper, a kneader, a 3-roll mill, a bead mill or an autorotation type stirrer. In the mixing, heating at a sufficient temperature may be conducted in order to attain favorable compatibility. After the dispersing and mixing, the curing accelerating agent may be added and mixed optionally.

### <Electrostatic Discharge Protector>

The electrostatic discharge protector of the present invention is used as a protective circuit for releasing an over current to earth in order to protect a device at the time of electrostatic discharging. At the time of normal operating at a low voltage, the electrostatic discharge protector of the present invention shows a high electric resistance value and feeds a current into the device without releasing to earth. While, when electrostatic discharge is caused, it shows a low electric resistance value promptly, an over current is released to earth and thereby the electrostatic discharge protector prevents the device from overcurrent feeding. When the transient phenomenon of electrostatic discharging is dissolved, the electric resistance value returns to a high electric resistance value and the electrostatic discharge protector feeds a current to the device. In the electrostatic discharge protector of the present invention, the discharge gap is filled with the discharge gap-filling member formed from the discharge gap filling composition containing the insulating binder component (C). Therefore, leakage current does not generate at the time of normal operating. For example, when a voltage of not more than DC10V is applied between the electrodes, the resistance value can be made to be not less than 10¹⁰Ω and thereby electrostatic discharge protection can be attained.

The electrostatic discharge protector of the present invention comprises at least two electrodes and one discharge gap-filling member. The two electrodes are disposed in a definite distance. The distance between the two electrodes is a discharge gap. The discharge gap-filling member is filled in this discharge gap. That is to say, the two electrodes are connected through the discharge gap-filling member. The discharge gap-filling member is formed by the discharge gap filling composition as described above. The electrostatic discharge protector of the present invention can be produced using the discharge gap filling composition by forming the discharge gap-filling member in the following manner.

That is, the discharge gap filling composition is firstly prepared in the above process, and then the composition is applied so as to contact with two electrodes on the substrate for forming the discharge gap by potting, screen printing or other method, and solidified or cured if necessary with heating to form the discharge gap-filling member on the substrate such as a flexible wiring substrate and the like.

The electrostatic discharge protector has a discharge gap distance of preferably not more than 500 μm, more preferably not less than 5 μm and not more than 300 μm, furthermore preferably not less than 10 μm and not more than 150 μm. When the discharge gap distance is over 500 μm, although even if the width of the electrodes for forming the discharge gap is set to be wide, the protector sometimes operates, it is easily to cause unevenness of electrostatic discharge performance in each product and it is difficult to conduct downsizing in the electrostatic discharge protector. While, when the discharge gap distance is less than 5 μm, it is also easily to cause unevenness of electrostatic discharge performance in each product due to the dispersion of the oxide film coated metal particles (A) and the layered substance (B) and also to cause short circuit. Herein, the discharge gap distance means the shortest distance between the electrodes.

The shape of the preferable electrode of the electrostatic discharge protector can be set arbitrarily with matching to the condition of the circuit board. In consideration of downsizing, the shape is a film having a rectangular cross section orthogonal to the thick direction and having a thickness of, for example, 5 to 200 μm. The preferable width of the electrodes of the electrostatic discharge protector is not less than 5 μm, and the electrode width is preferably wider because energy at the time of electrostatic discharging can be diffused. While when the electrode width of the electrostatic discharge protector has a sharp shape and is less than 5 μm, the periphery members including the electrostatic discharge protector itself are damaged largely because energy at the time of electrostatic discharging concentrates.

In the discharge gap filling composition of the present invention, the adhesion with substrate is sometimes insufficient due to the material of the substrate provided with the discharge gap, electrostatic discharge has very high energy and the volume occupancy of the oxide film coated metal particles (A) is high. Accordingly, when the discharge gap-filling member is formed and then the protective layer of the resin composition is provided so as to cover this discharge gap-filling member, the high voltage resistance is given and the repeating resistance is improved and also it is possible to prevent the electronic circuit board from contamination caused by falling of the oxide film coated metal particles (A) which volume occupancy is high.

Examples of the resin used for the protecting layer are a natural resin, a modified resin and an oligomer synthetic resin.

As the natural resin, rosin is a typical resin. Examples of the modified resin are a rosin derivative and a rubber derivative. Examples of the oligomer synthetic resin are resins which are simultaneously used with the polysiloxane compound of the electrostatic discharge protector, for example, an epoxy resin, an acrylic resin, a maleic acid derivative, a polyester resin, a melamine resin, a polyurethane resin, a polyimide resin, a polyamic resin and a polyimide/amide resin.

The resin composition preferably contains a curing resin capable of being cured by heat or an ultraviolet ray in order to keep the coated film strength.

Examples of the thermosetting resin are a carboxyl group-containing polyurethane resin, an epoxy compound, a combination of an epoxy compound with a compound containing an acid anhydride group, a carboxyl group, an alcoholic group or an amino group, and a combination of a carbodiimide-containing compound with a compound containing a carboxyl group, an alcoholic group or an amino group.

Examples of the epoxy compound are epoxy compounds having two or more epoxy groups in one molecule, such as a bisphenol A type epoxy resin, a hydrogenated bisphenol A type epoxy resin, a brominated bisphenol A type epoxy resin, a bisphenol F type epoxy resin, a novolac type epoxy resin, a phenol novolac type epoxy resin, a cresol novolac type epoxy resin, an alicyclic epoxy resin, a N-glycydyl type epoxy resin, a bisphenol A novolac type epoxy resin, a chelate type epoxy resin, a glyoxal type epoxy resin, an amino group-containing epoxy resin, a rubber modified epoxy resin, a dicyclopentadiene phenolic type epoxy resin, a silicon modified epoxy resin and a ε-caprolactone modified epoxy resin.

In order to add flame resistance, an epoxy compound having a structure that an atom such as chlorine, bromine, or other halogen or phosphorus is introduced may be used. Furthermore, it is possible to use a bisphenol S type epoxy resin, a diglycidyl phthalate resin, a heterocyclic epoxy resin, a bixylenol type epoxy resin, a biphenol type epoxy resin and a tetraglycidyl xylenoyl ethane resin.

It is preferred to use an epoxy compound having two or more epoxy groups in one molecule as the epoxy compound, but it is possible to simultaneously use an epoxy compound having only one epoxy group in one molecule. An example of the compound containing a carboxyl group is an acrylate compound, which is not particularly limited. The alcoholic group-containing compound and the amino group-containing compound are not also particularly limited.

Examples of the ultraviolet ray curing resin are an acrylic copolymer which is a compound containing two or more ethylic unsaturated groups, an epoxy(meth)acrylate resin and an urethane(meth)acrylate resin.

The resin composition for forming the protective layer can optionally contain a curing accelerating agent, a filler, a solvent, a foaming agent, a defoaming agent, a leveling agent, a lubricant, a plasticizer, an anticorrosive agent, a viscosity regulating agent and a colorant.

Although the thickness of the protective layer is not particularly limited, it is preferred that the protective layer completely cover the discharge gap-filling member formed from the discharge gap filling composition. When the protective layer has a defect, there is strong possibility that crack will be generated by high energy at the time of electrostatic discharging.

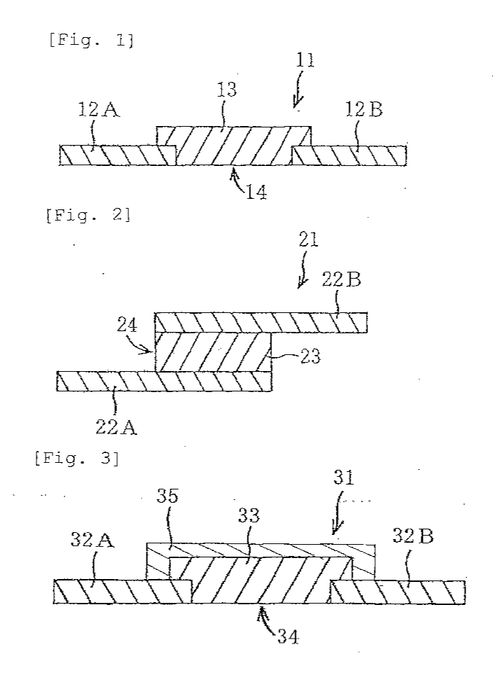

FIG. 1 is a longitudinal cross section showing an electrostatic discharge protector 11, which is one embodiment of the electrostatic discharge protector of the present invention. The electrostatic discharge protector 11 is formed from an electrode 12A, an electrode 12B and a discharge gap-filling member 13. The electrode 12A and electrode 12B are disposed so that their axial directions are identical and their head surfaces are faced each other. A discharge gap 14 is formed between the head surfaces of the electrodes 12A and 12B faced each other. The discharge gap-filling member 13 is filled in the discharge gap 14 so as to cover the head surface of the electrode 12A faced to the head surface of the electrode 12B and the head surface of the electrode 12B faced to the head surface of the electrode 12A from the upper side and to be contact with the head surfaces. The width of the discharge gap 14, namely the distance of the head surfaces of the electrodes 12A and 12B faced each other is preferably not less than 5 μm and not more than 300 μm.

FIG. 2 is a longitudinal cross section showing an electrostatic discharge protector 21, which is another embodiment of the electrostatic discharge protector of the present invention. The electrostatic discharge protector 21 is formed from an electrode 22A, an electrode 22B and a discharge gap-filling member 23. The electrode 22A and electrode 22B are parallel disposed so that they are piled up in their head parts in the vertical direction. A charge gap 24 is formed on the parts of the electrodes 22A and 22B piled up each other in the vertical direction. The discharge gap-filling member 23 has a rectangle cross-section and is filled in the discharge gap 24. The width of the discharge gap 24, namely distance between the electrodes 22A and 22B in the part where the electrodes 22A and 22B are piled up in the vertical direction is preferably not less than 5 μm and not more than 300 μm.

FIG. 3 is a longitudinal cross section showing an electrostatic discharge protector 31, which is one embodiment of the electrostatic discharge protector of the present invention. The electrostatic discharge protector 31 is obtainable by providing a protective layer in the electrostatic discharge protector 11 and is formed from an electrode 32A, an electrode 32B, a discharge gap-filling member 33 and a protective layer 35. The electrode 32A and electrode 32B are disposed so that their axial directions are identical and their head surfaces are faced each other. A discharge gap 34 is formed between the head surfaces of the electrodes 32A and 32B faced each other. The discharge gap-filling member 33 is filled in the discharge gap 34 so as to cover the head surface of the electrode 32A faced to the head surface of the electrode 32B and the head surface of the electrode 32B faced to the head surface of the electrode 32A from the upper side and to be contact with the head surfaces. The protective layer 35 is provided to cover the surface of the discharge gap-filling member 33 except for the bottom thereof. The width of the discharge gap 34, namely the distance of the head surfaces of the electrodes 32A and 32B faced each other is preferably not less than 5 μm and not more than 300 μm.

### EXAMPLE

The present invention will be described in more detail with reference to the following examples, but they should not limit it.

### <Preparation of Electrostatic Discharge Protector>

On a wiring substrate that a pair of electrode patterns having a film thickness of 12 μm, a discharge gap distance of 50 μm and an electrode width of 500 μm was formed on a polyimide film having a film thickness of 25 μm, the discharge gap filling composition prepared by the method as described later was applied using a flat needle having a tip diameter of 2 mm and filled in the discharge gap so as to cover the electrode patterns. Thereafter, the wiring substrate was kept in a temperature controlled vessel at 120° C. for 60 min to form a discharge gap-filling member. Thereafter, a soluble high transparent polyimide (Trade name: PI-100 manufactured by Maruzen Petrochemical Inc.) was dissolved in γ-butyrolactone so that the solid component concentration was 20%. The polyimide solution was applied and completely covered on the discharge gap-filling member and dried at 120° C. for 30 min to prepare an electrostatic discharge protector.

### <Evaluation Method for Insulating Properties at the Time of a Normal Operating Voltage>

Concerning the electrode parts provided in the both ends of the electrostatic discharge protector, the resistance at the time of application of DC10V was measured using an insulation-resistance meter “MEGOHMNETER SM-8220” and taken as a resistance at the time of normal operating.

A: The electric resistance value is not less than 10¹⁰Ω.
B: The electric resistance value is less than 10¹⁰Ω.

### <Evaluation Method for Operating Voltage>

Using a semiconductor electrostatic tester ESS-6008 (manufactured by NOISE LABORATORY Inc.), the peak current at an arbitrary applied voltage was measured. The resultant electrostatic discharge protector was set and the same applied voltage was applied thereon. The peak current was measured. When the peak current measured was 70% or more of the peak current in the case of no electrostatic discharge protector, its applied voltage was taken as an operating voltage.

A: The operating voltage is not less than 500 and less than 750V.
B: The operating voltage is not less than 750 and less than 1000V.
C: The operating voltage is not less than 1000 and less than 2000V.
D: The operating voltage is not less than 2000, or the application at 1000V causes short circuit and the insulating properties do not recover.

### <Evaluation Method for High Voltage Resistance>

The resultant electrostatic discharge protector was fixed in a semiconductor electrostatic tester ESS-6008 (manufactured by NOISE LABORATORY Inc.) and a 8 kV voltage was applied thereon 10 times, and then the resistance value in application of DC10V was measured using a insulation resistance meter MEGOHMMETER SM-8220. The resistance value was evaluated as high voltage resistance.

A: The resistance value is not less than 10¹⁰Ω.
B: The resistance value is not less than 10⁸Ω and less than 10¹⁰Ω.
C: The resistance value is less than 10⁸Ω.

### <Synthetic Example of Binder Component (C)>

### Polysiloxane Compound

To a reactor equipped with a reflux condenser and a stirrer, 100 parts of methyltrimethoxysilane, 60 parts of Alumina sol 520 (an acid aqueous solution, a solid component concentration of 20% manufactured by Nissan Chemical Industries Inc.) and 15 parts of isopropyl alcohol were added and reacted with heating at 60° C. for 4 hr. Thereafter, 5 parts of γ-glycidoxy propyl trimethoxysilane was added to the reactant and further reacted at 60° C. for 1 hr. To the reactant, 80 parts of isopropylalcohol was added to prepare a polysiloxane compound solution. The solid component concentration was 25%. From the polysiloxane compound solution, an alumina component was removed using a centrifugal separator and the supernatant was filtered off with a filter having a hole diameter of 0.45 μm. The polysiloxane compound prepared from the supernatant was measured by a GPC method. The weight average molecular weight relative to polystyrene was 9,300.

### Example 1

To 50.0 g of the polysiloxane compound prepared in the synthetic example, 25 g of Trade name “08-0076” (aluminum powder, average particle diameter of 2.5 μm manufactured by Toyo aluminum Inc.) as the oxide film coated metal particles (A), 2.5 g of Trade name “Losentite SPN” (smectite group, scale form, average particle diameter of 2 μm manufactured by Coop Chemical Inc.) as the layered substance (B) were added and stirred using a homogenizer at 2000 rpm for 15 min to prepare a discharge gap filling composition which, as a solid component volume occupancy, contained 43% by volume of the oxide film coated metal particles (A) and 4% by volume of a layered substance (B). Using the discharge gap filling composition, an electrostatic discharge protector was prepared by the above method. The resistance at the time of normal operating, operating voltage and high voltage resistance were evaluated. The results are shown in Table 1.

### Example 2

To 25.0 g of the polysiloxane compound prepared in the synthetic example, 60 g of Trade name “08-0076” (aluminum powder, average particle diameter of 2.5 μm manufactured by Toyo aluminum Inc.) as the oxide film coated metal particles (A), 4.0 g of Trade name “UF-G5” (Artificial graphite fine powder, scale form, average particle diameter of 3 μm manufactured by Showa Denko K.K.) as the layered substance (B) were added and stirred using a homogenizer at 2000 rpm for 15 min. Furthermore, 11 g of “X14-B3445 A agent” and 11 g of “X14-B3445 B agent” (both of the agents were silicon resins manufactured by Momentive Performance materials Japan Inc.) were added to the mixture and stirred using the homogenizer at 2000 rpm for 10 min to prepare a discharge gap filling composition which as a solid component volume occupancy, contained 44% by volume of the oxide film coated metal particles (A) and 5% by volume of a layered substance (B). Using the discharge gap filling composition, an electrostatic discharge protector was prepared by the above method. The resistance at the time of normal operating, operating voltage and high voltage resistance were evaluated.

The results are shown in Table 1.

### Example 3

To 15.0 g of the polysiloxane compound prepared in the synthetic example, 70 g of Trade name “08-0076” (aluminum powder, average particle diameter of 2.5 μm manufactured by Toyo aluminum Inc.) as the oxide film coated metal particles (A), 0.1 g of Trade name “VGCF” (Gas phase grown carbon fiber, average fiber diameter of 0.15 μm and an average fiber length of 10 μm manufactured by Showa Denko K.K.) as the layered substance (B) were added and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) were added as the polysiloxane compound to the mixture and stirred using the homogenizer at 2000 rpm for 10 min to prepare a discharge gap filling composition which, as a solid component volume occupancy, contained 46% by volume of the oxide film coated metal particles (A) and 0.1% by volume of a layered substance (B). Using the discharge gap filling composition, an electrostatic discharge protector was prepared by the above method. The resistance at the time of normal operating, operating voltage and high voltage resistance were evaluated. The results are shown in Table 1.

### Example 4

To 25.0 g of the polysiloxane compound prepared in the synthetic example, 200 g of Trade name “4SP-10” (nickel powder, average particle diameter of 10 μm manufactured by Nikko Lika Co., Ltd.) as the oxide film coated metal particles (A), 4.0 g of Trade name “UF-G5” (Artificial graphite fine powder, scale form, average particle diameter of 3 μm manufactured by Showa Denko K.K.) were added and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) were added as the polysiloxane compound to the mixture and stirred using the homogenizer at 2000 rpm for 10 min to prepare a discharge gap filling composition which, as a solid component volume occupancy, contained 39% by volume of the oxide film coated metal particles (A) and 3% by volume of a layered substance (B). Using the discharge gap filling composition, an electrostatic discharge protector was prepared by the above method. The resistance at the time of normal operating, operating voltage and high voltage resistance were evaluated. The results are shown in Table 1.

### Example 5

To 25.0 g of the polysiloxane compound prepared in the synthetic example, 35 g of Trade name “08-0075” (aluminum powder, average particle diameter of 6.8 μm manufactured by Toyo aluminum Inc.) as the oxide film coated metal particles (A), 3.5 g of Trade name “UF-G5” (Artificial graphite fine powder, scale form, average particle diameter of 3 μm manufactured by Showa Denko K.K.) were added and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) as the polysiloxane compound were added to the mixture and stirred using the homogenizer at 2000 rpm for 10 min to prepare a discharge gap filling composition which, as a solid component volume occupancy, contained 27% by volume of the oxide film coated metal particles (A) and 3% by volume of a layered substance (B). Using the discharge gap filling composition, an electrostatic discharge protector was prepared by the above method. The resistance at the time of normal operating, operating voltage and high voltage resistance were evaluated.

The results are shown in Table 1.

### Example 6

To 25.0 g of the polysiloxane compound prepared in the synthetic example, 70 g of Trade name “08-0076” (aluminum powder, average particle diameter of 2.5 μm manufactured by Toyo aluminum Inc.) as the oxide film coated metal particles (A), 0.1 g of Trade name “UF-G5” (Artificial graphite fine powder, scale form, average particle diameter of 3 μm manufactured by Showa Denko K.K.) were added and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) as the polysiloxane compound were added to the mixture and stirred using the homogenizer at 2000 rpm for 10 min to prepare a discharge gap filling composition which, as a solid component volume occupancy, contained 44% by volume of the oxide film coated metal particles (A) and 0.1% by volume of the layered substance (B). Using the discharge gap filling composition, an electrostatic discharge protector was prepared by the above method. The resistance at the time of normal operating, operating voltage and high voltage resistance were evaluated.

The results are shown in Table 1.

### Example 7

An electrostatic discharge protector without a protective layer was prepared using the same discharge gap filling composition as that in Example 2. The resistance at the time of normal operating, operating voltage and high voltage resistance were evaluated.

The results are shown in Table 1.

### Comparative Example 1

To 25.0 g of the polysiloxane compound prepared in the synthetic example, 100 g of Trade name “08-0076” (aluminum powder, average particle diameter of 2.5 μm manufactured by Toyo aluminum Inc.) as the oxide film coated metal particles (A) was added and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) as the polysiloxane compound were added to the mixture and stirred using the homogenizer at 2000 rpm for 10 min to prepare a discharge gap filling composition which, as a solid component volume occupancy, contained 53% by volume of the oxide film coated metal particles (A) and no layered substance (B). Using the discharge gap filling composition, an electrostatic discharge protector for the comparison was prepared for the comparison by the above method. The resistance at the time of normal operating, operating voltage and high voltage resistance were evaluated.

The results are shown in Table 1.

### Comparative Example 2

To 25.0 g of the polysiloxane compound prepared in the synthetic example, 50 g of Trade name “UF-G5” (Artificial graphite fine powder, scale form, average particle diameter of 3 μm manufactured by Showa Denko K.K.) was added as the layered substance (B) and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) as the polysiloxane compound were added to the mixture and stirred using the homogenizer at 2000 rpm for 10 min to prepare a discharge gap filling composition which, as a solid component volume occupancy, contained 41% by volume of the layered substance (B) and no oxide film coated metal particles (A). Using the discharge gap filling composition, an electrostatic discharge protector was prepared for the comparison by the above method. The resistance at the time of normal operating, operating voltage and high voltage resistance were evaluated. The results are shown in Table 1.

### Comparative Example 3

To 25.0 g of the polysiloxane compound prepared in the synthetic example, 10 g of Trade name “UF-G5” (Artificial graphite fine powder, scale form, average particle diameter of 3 μm manufactured by Showa Denko K.K.) was added as the layered substance (B) and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) as the polysiloxane compound were added to the mixture and stirred using the homogenizer at 2000 rpm for 10 min to prepare a discharge gap filling composition which, as a solid component volume occupancy, contained 12% by volume of the layered substance (B) and no oxide film coated metal particles (A). Using the discharge gap filling composition, an electrostatic discharge protector was prepared for the comparison by the above method. The resistance at the time of normal operating, operating voltage and high voltage resistance were evaluated.

The results are shown in Table 1.

### Comparative Example 4

To 25.0 g of the polysiloxane compound prepared in the synthetic example, 200 g of tungsten powder (spherical form, average particle diameter of 3 μm manufactured by Japan Tungsten Inc.) as the metal particles having no oxide film and 3.5 g of Trade name “UF-G5” (Artificial graphite fine powder, scale form, average particle diameter of 3 μm manufactured by Showa Denko K.K.) as the layered substance (B) were added and stirred using a homogenizer at 2000 rpm for 15 min. Furthermore, 15 g of “X14-B3445 A agent” and 15 g of “X14-B3445 B agent” (both of the agents were silicon resins manufactured by Momentive Performance materials Japan Inc.) as the polysiloxane compound were added to the mixture and stirred using the homogenizer at 2000 rpm for 10 min to prepare a discharge gap filling composition which, as a solid component volume occupancy, contained 27% by volume of the metal particles having no oxide film and 3% by volume of the layered substance (B). Using the discharge gap filling composition, an electrostatic discharge protector was prepared by the above method. The resistance at the time of normal operating, operating voltage and high voltage resistance were evaluated. The results are shown in Table 1.

### Comparative Example 5

To 25.0 g of the polysiloxane compound prepared in the synthetic example, 60 g of Trade name “08-0076” (aluminum powder, average particle diameter of 2.5 μm manufactured by Toyo aluminum Inc.) as the oxide film coated metal particles (A) and 26 g of tungsten powder (spherical form, average particle diameter of 3 μm manufactured by Japan Tungsten Ltd.) as a non-layered substance were added and stirred using a homogenizer at 2000 rpm for 15 min. Furthermore, 11 g of “X14-B3445 A agent” and 11 g of “X14-B3445 B agent” (both of the agents were silicon resins manufactured by Momentive Performance materials Japan Inc.) as the polysiloxane compound were added to the mixture and stirred using the homogenizer at 2000 rpm for 10 min to prepare a discharge gap filling composition which, as a solid component volume occupancy, contained 44% by volume of the oxide film coated metal particles (A) and 5% by volume of the non-layered substance. Using the discharge gap filling composition, an electrostatic discharge protector was prepared by the above method. The resistance at the time of normal operating, operating voltage and high voltage resistance were evaluated.

The results are shown in Table 1.

TABLE 1

| | Resistance at | | |
|---|---|---|---|
| | the time of | | |
| | normal | Operating | High voltage |
| | operating | voltage | resistance |
| Example 1 | A | C | B |
| Example 2 | A | A | A |
| Example 3 | A | A | A |
| Example 4 | A | B | B |
| Example 5 | A | C | A |
| Example 6 | A | C | A |
| Example 7 | A | A | A |
| Comparative | A | D | C |
| Example 1 | | | |
| Comparative | B | B | C |
| Example 2 | | | |
| Comparative | A | D | B |
| Example 3 | | | |
| Comparative | B | D | C |
| Example 4 | | | |
| Comparative | A | D | C |
| Example 5 | | | |

As is clear from the results of Table 1, the electrostatic discharge protector formed using the discharge gap filling composition which comprises the oxide film coated metal particles (A), the layered substance (B) and the binder component (C) has excellent resistance at the time of normal operating, operating voltage and high voltage resistance.

### POSSIBILITY OF INDUSTRIAL USE

Using the discharge gap filling composition which comprises the oxide film coated metal particles (A), the layered substance (B) and the binder component (C), the electrostatic discharge protector having a free shape can be prepared and thereby the downsizing and decrease in cost in a measure of ESD can be attained.

### DESCRIPTION OF MARKS

11 . . . Electrostatic discharge protector
12A . . . Electrode
12B . . . Electrode
13 . . . Discharge gap-filling member
14 . . . Discharge gap
21 . . . Electrostatic discharge protector
22A . . . Electrode
22B . . . Electrode
23 . . . Discharge gap-filling member
24 . . . Discharge gap
31 . . . Electrostatic discharge protector
32A . . . Electrode
32B . . . Electrode
33 . . . Discharge gap-filling member
34 . . . Discharge gap
35 . . . Protective layer

1. A discharge gap filling composition used for electrostatic discharge protectors which composition comprises oxide film coated metal particles (A), a layered substance (B) and a binder component (C).

2. The discharge gap filling composition according to claim 1 wherein the oxide film coated metal particles (A) comprise particles of a single metal of at least one metal selected from the group consisting of manganese, niobium, zirconium, hafnium, tantalum, molybdenum, vanadium, nickel, cobalt, chromium, magnesium, titanium and aluminum, or comprise particles of at least two different metals of the above metals.

3. The discharge gap filling composition according to claim 1 wherein the layered substance (B) is at least one selected from a clay mineral crystal (B1) and a layered carbon material (B2).

4. The discharge gap filling composition according to claim 3 wherein the layered substance (B) is the layered carbon material (B2).

5. The discharge gap filling composition according to claim 4 wherein the layered carbon material (B2) is at least one selected from the group consisting of carbon nano tube, gas phase grown carbon fiber, carbon fullerene, graphite and a carbyne carbon material.

6. The discharge gap filling composition according to claim 1 wherein the binder component (C) comprises a polysiloxane compound.

7. An electrostatic discharge protector comprising a discharge gap and a discharge gap filling material that is filled in the discharge gap wherein the discharge gap filling material comprises the discharge gap filling composition as claimed in claim 1 and the discharge gap has a distance of 5 to 300 μm.

8. An electronic circuit board provided with the electrostatic discharge protector as claimed in claim 7.

9. The electronic circuit board according to claim 8, which is a flexible electronic circuit board.

10. An electronic device provided with the electronic circuit board as claimed in claim 9.
